(19) United States
(12) Patent Application Publication
(10) Pub. No.: US 2012/0025929 A1
(43) Pub. Date: Feb. 2, 2012

(54) FILTER WITH IMPROVED IMPEDANCE MATCH TO A HYBRID COUPLER

(76) Inventors: Max Ward Muterspaugh, Westfield, IN (US); Daniel Mark Hutchinson, Carmel, IN (US); Andrew Eric Bowyer, Indianapolis, IN (US)

(21) Appl. No.: 13/138,834

(22) PCT Filed: Dec. 21, 2009
(86) PCT No.: PCT/US09/06686

§ 371 Date: Oct. 6, 2011

Related U.S. Application Data
(60) Provisional application No. 61/172,932, filed on Apr. 27, 2009.

(51) Int. Cl. H03H 7/46; H03H 7/01

(52) U.S. Cl. 333/126; 333/175

(57) ABSTRACT

The present invention concerns a bandstop filter for preventing signals of frequencies used for inter-device communications in a television signal distribution system from interfering with a signal source. The filter is designed to work with a signal splitter and reduce the negative impact on inter-device communication through the splitter caused by conventional bandstop filters. The filter adds a section to a bandstop filter to provide a resistive load and high output impedance at the port feeding the splitter largely through the action of a parallel resonant circuit.

### CROSS REFERENCE TO RELATED APPLICATION

This application claims priority to and all benefits accruing from provisional applications filed in the United States Patent and Trademark Office on Apr. 27, 2009 and assigned Ser. No. 61/172,932.

### BACKGROUND OF THE INVENTION

The present invention generally relates to a bandstop filter for preventing signals of frequencies used for inter-device communications in a television signal distribution system from interfering with a signal source. The filter is designed to work with a signal splitter and reduce the negative impact on inter-device communication through the splitter caused by conventional bandstop filters. The filter adds a section to a bandstop filter to provide a resistive load and high output impedance at the port feeding the splitter largely through the action of a parallel resonant circuit.

This section is intended to introduce the reader to various aspects of art, which may be related to various aspects of the present invention that are described below. This discussion is believed to be helpful in providing the reader with background information to facilitate a better understanding of the various aspects of the present invention. Accordingly, it should be understood that these statements are to be read in this light, and not as admissions of prior art.

Television programming is commonly received from satellite or cable sources. Received signals are generally delivered through the home via coaxial cable to a set-top box (STB) associated with a television display device. In some environments, multiple STBs are present, each generally connected to a separate display. One or more of the STBs may contain digital video recorder (DVR) capability. A user of one of the STBs may wish to view programming that has been recorded on another STB or perform other functions. To facilitate such interaction, networking schemes such as the Multimedia over Coax Alliance (MoCA™) standard have been created to allow communication of content between STBs.

STBs are generally connected to a coaxial cable distribution system using hybrid splitters. Content from a satellite or cable source is delivered to the STBs over this distribution system within a first frequency band. A separate second frequency band is then used for communication between devices.

A band-stop filter may be used to prevent interference of MoCA communications with satellite signal reception and processing. In addition, filters may be inserted to prevent overload conditions. The impedance mismatch from these filters, however, may distort the MoCA frequency band response. A new filter design is needed to provide the required attenuation to prevent overloading while maintaining a desired impedance to the splitter device. The invention described herein addresses this and/or other problems.

### SUMMARY OF THE INVENTION

In order to solve the problems described above, the present invention concerns a bandstop filter for preventing signals of frequencies used for inter-device communications in a television signal distribution system from interfering with a signal source. The filter is designed to work with a signal splitter and reduce the negative impact on inter-device communication through the splitter caused by conventional bandstop filters. The filter adds a section to a bandstop filter to provide a resistive load and high output impedance at the port feeding the splitter largely through the action of a parallel resonant circuit. This and other aspects of the invention will be described in detail with reference to the accompanying Drawings.

### BRIEF DESCRIPTION OF THE DRAWINGS

The above-mentioned and other features and advantages of this invention, and the manner of attaining them, will become more apparent, and the invention will be better understood, by reference to the following description of embodiments of the invention taken in conjunction with the accompanying drawings, wherein:

FIG. 1 is a diagram of an exemplary embodiment of a satellite television system;

FIG. 2 is a circuit diagram of an example of a conventional splitter;

FIG. 3 is a graph of the frequency response for transmissions between two splitter outputs with a conventional bandstop filter attached to the splitter input;

FIG. 4 is a circuit diagram of a filter in accordance with the present invention;

FIG. 5 is a graph of the frequency response of the filter of FIG. 4;

FIG. 6 is a graph of the frequency response for transmissions between two splitter outputs with the filter of FIG. 4 connected to the splitter input;

FIG. 7 is a graph of the frequency response for transmissions between two splitter outputs with the filter input connected to a 3′ RG-59 coaxial cable without a termination;

FIG. 8 is a graph of the frequency response for transmissions between two splitter outputs with a modified filter output resistor value;

The exemplifications set out herein illustrate preferred embodiments of the invention, and such exemplifications are not to be construed as limiting the scope of the invention in any manner.

### DESCRIPTION OF THE PREFERRED EMBODIMENTS

As described herein, the present invention provides a bandstop filter for preventing signals of frequencies used for inter-device communications in a television signal distribution system from interfering with a signal source. The filter is designed to work with a signal splitter and reduce the negative impact on inter-device communication through the splitter caused by conventional bandstop filters. The filter adds a section to a bandstop filter to provide a resistive load and high output impedance at the port feeding the splitter largely through the action of a parallel resonant circuit.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

The present invention may be implemented as a separate filter element or in a splitter or coupler that is used as part of a system for distributing signals to and amongst set-top boxes (STBs) or video decoders that are capable of receiving satellite signals, cable television signals, or other transmitted television signals.

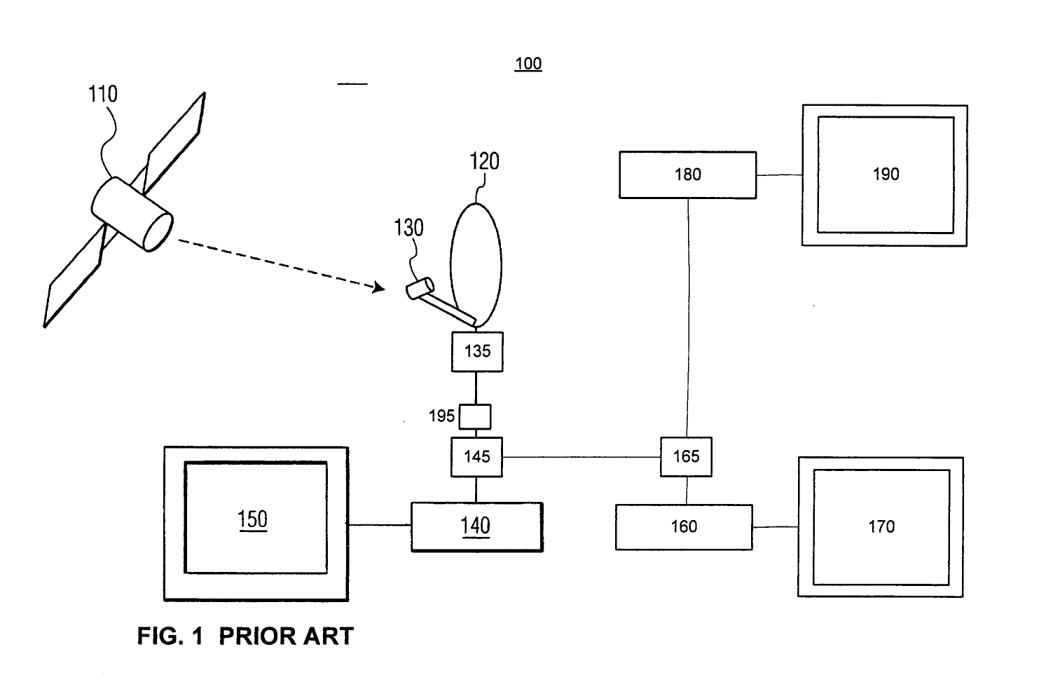

FIG. 1 is a diagram of an exemplary embodiment of a satellite television system. The satellite television system operates to broadcast microwave signals to a wide broadcast area by transmitting the signals from a geosynchronous satellite 110. A geosynchronous satellite 110 orbits the earth once each day at approximately 35,786 kilometers above the surface of the Earth. Such broadcast satellites 110 generally orbit around the equator and remain in the same position with respect to positions on the ground, allowing a satellite receiving antenna 120 to maintain a fixed look angle.

Satellite 110 receives signals from uplink transmitters and then rebroadcasts the signals back to earth using a set of transponders utilizing a variety of transmission frequencies. The altitude of the transmitting satellite 110 allows subscribers in a wide geographical area to receive the signal.

The distance from the earth and the severe power conservation requirements of the satellite result in a relatively weak signal being received at the antenna 120. It is therefore critical that the signal be amplified as soon as possible after it is received by the antenna. This requirement is achieved through the placement of a low noise block downconverter (LNB) 130 at the feed horn of the parabolic dish antenna 120. In a simple single set-top box configuration, the selected signal from the LNB 130 may travel along a coaxial cable to a digital satellite set-top box 140, which tunes a desired channel for presentation on television display device 150. In some installations, a single-wire multi-switch (SWM) 135 may be used to multiplex signals from multiple LNBs and their multiple polarities onto a single coaxial cable for delivery into the home.

Splitters 145 and 165 may be used to split the signals to cables running to other set top boxes 160 and 180, connected to television display devices 170 and 190, respectively. A similar configuration may exist in a cable-based installation. A single feed from the local cable distribution system may enter the house and be split to coaxial cables running to multiple cable set-top boxes.

The cabling and splitters used to carry received satellite signals from SWM 135 to set-top boxes 140, 160, and 180, and carry control information back to the SWM 135, may also be used for communication between set-top boxes. For instance, a set-top box 140 containing a DVR may provide access to recorded content to other set-top boxes 160 and 180 in the home. The Multimedia over Coax Alliance (MoCA™) standard describes one method of providing such functionality. In the case of a satellite television system, these digital home networking (DHN) communications between boxes occur at frequencies below those for LNB-to-STB or SWM-to-STB communications. While the following discussion is written with regard to MoCA transmissions occurring at frequencies below the satellite coaxial transmission frequencies, the invention may also be applied to other DHN schemes with other signals transmitted at frequencies above or below the DHN frequencies, or both. In the case of cable television, for instance, DHN communications may occur at frequencies above those of the cable television transmissions.

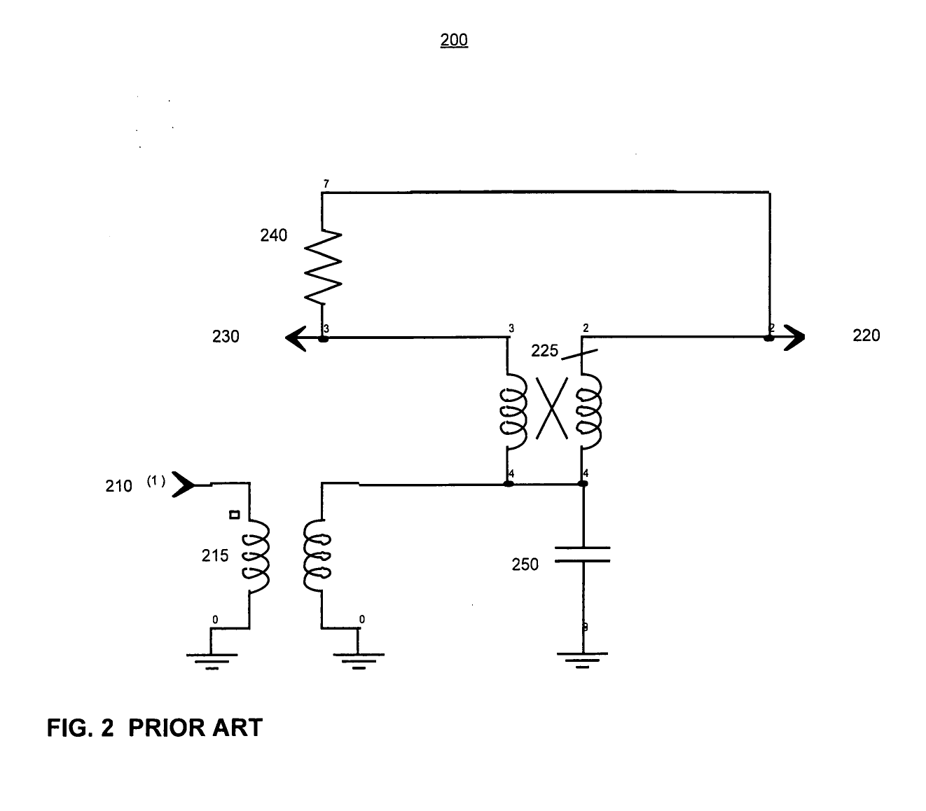

FIG. 2 is a diagram of a splitter 200 for use in a satellite television system. LNB signals are received at input port 210 and distributed to output ports 220 and 230. Transformer 215 is an impedance step-down transformer feeding transformer 225. Normally, a hybrid splitter 200, or coupler, maintains a high degree of isolation between the two outputs 220 and 230, preventing signals from traveling from one port to the other. This is achieved by adding a bridging resistor 240 between the outputs 220 and 230. In this example, a capacitor 250 is added to enhance the high frequency performance.

In DHN applications, however, it is necessary to allow DHN signals to pass from port 220 to 230, and vice-versa, to allow communications between STBs, but to maintain the isolation between the ports with regard to the LNB signals. For certain MoCA applications, it is desirable to maintain the isolation in the satellite band of 950 to 2050 MHz, but to allow the MoCA signal between 473 and 603 MHz to pass through the splitter 200. The output-to-input or input-to-output loss is nominally around 3 dB and does not prevent communication. The large isolation between outputs created by resistor 240, however, creates a problem for such communications. In a MoCA system, the splitter may therefore be designed to provide a compromise between attenuation of the MoCA signal and isolation in the satellite band.

The splitter 200 may be modified by inserting a filter element in series with the bridging resistor 240 such that the effect of said bridging resistor is removed in the MoCA frequency band, but coupled into the circuit for the distribution frequency band. For instance, a parallel resonant LC circuit for 550 MHz may be used to allow the MoCA signals to be passed. Performance may be enhanced by choosing an L/C ratio to achieve the desired transmission performance at the MoCA band edges. A higher L/C ratio produces a lower impedance at the band edges (473 and 603 MHz), but must be compromised with isolation at the lower edge of the satellite band.

In addition, the use of a filter 195, shown in FIG. 1, is desirable between the splitter input and the satellite signal source to block the high level MOCA signals that might otherwise cause distortion and interference due to harmonics in the satellite reception, or to prevent overload conditions. Such a band-stop filter 195 may be a separate system element or housed within SWM 135 or splitter 145. The impedance mismatch from such a filter, however, may distort the MoCA frequency band response, causing erratic and undesirably high attenuation in the output-to-output splitter path.

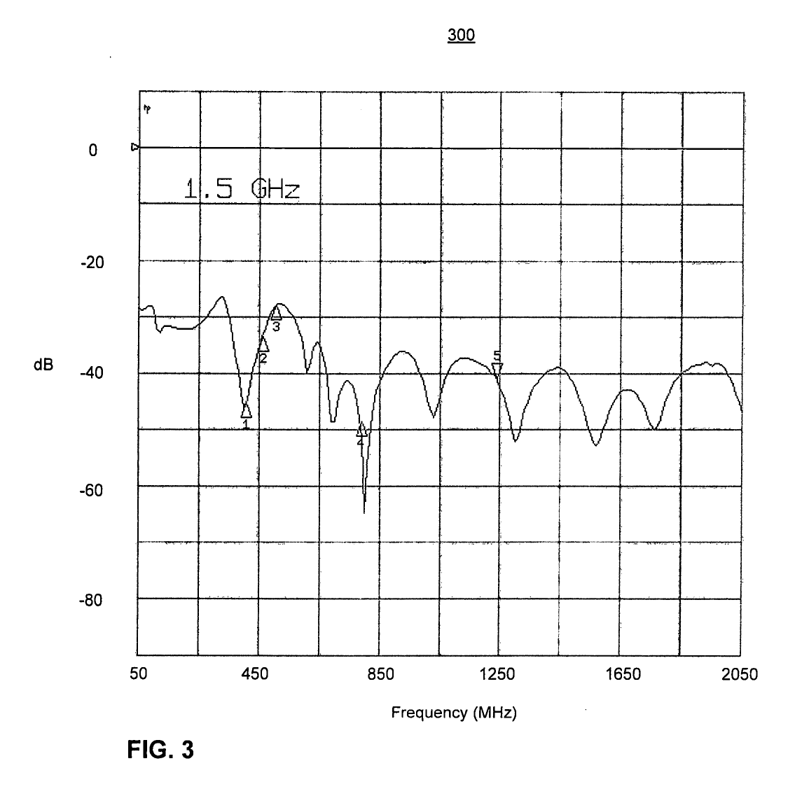

FIG. 3 illustrates this problem, showing the attenuation of signals at various frequencies transmitted from output 5 to output 7 of an 8-way splitter with a Microphase Corporation bandstop filter connected to the splitter input and unused splitter outputs terminated in 75 ohms. The x-axis shows signal frequency. The y-axis shows attenuation in dB. Note that there is 11.6 dB loss in the matching pads used in the test system. With a 75 ohm termination on the splitter input, this path would be controlled to provide a nominal loss of approximately 25 dB. With the Microphase filter, this loss increased to 40 dB at some points and varied 10 dB or more over the MoCA band. Losses of this level may prevent, or reduce the reliability of, MoCA communication between devices attached to the splitter outputs. A new filter design is needed to provide the required attenuation while maintaining the desired impedance to the splitter device.

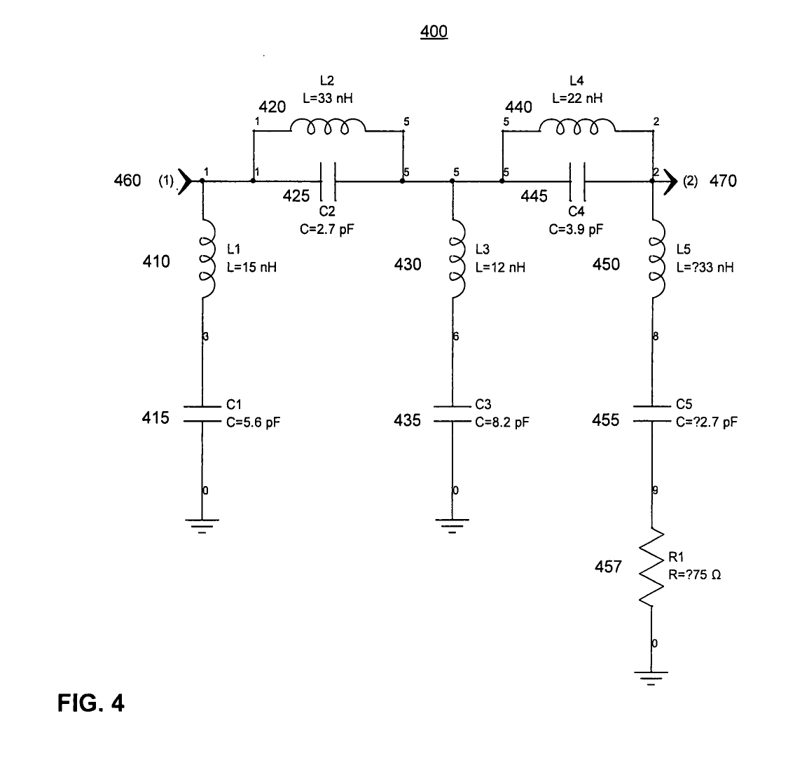

FIG. 4 is a diagram of a filter that addresses this problem. The filter adds a section to provide a resistive load over the MoCA band at the port feeding the splitter. Signals from LNBs are received at input port 460 and passed to output port 470. Port 470 may then be connected to input 210 of the splitter 200. The bandstop filter is designed to provide a high output impedance at port 470 largely by the action of the parallel resonant circuit formed by inductor 440 and capacitor 445. Components 410 through 445 comprise a normal bandstop filter with the required rejection to port 460, which is connected to the satellite signal source.

Inductor 450 and capacitor 455 are series resonant in the MOCA band (550 MHz) and couple resistor 457 to port 470 to provide a match for the MOCA band. Resistor 457 can be altered from 75 ohms to provide a controlled mismatch to the splitter. This can improve (reduce) the attenuation in the MOCA band while maintaining a higher desirable isolation in the satellite band.

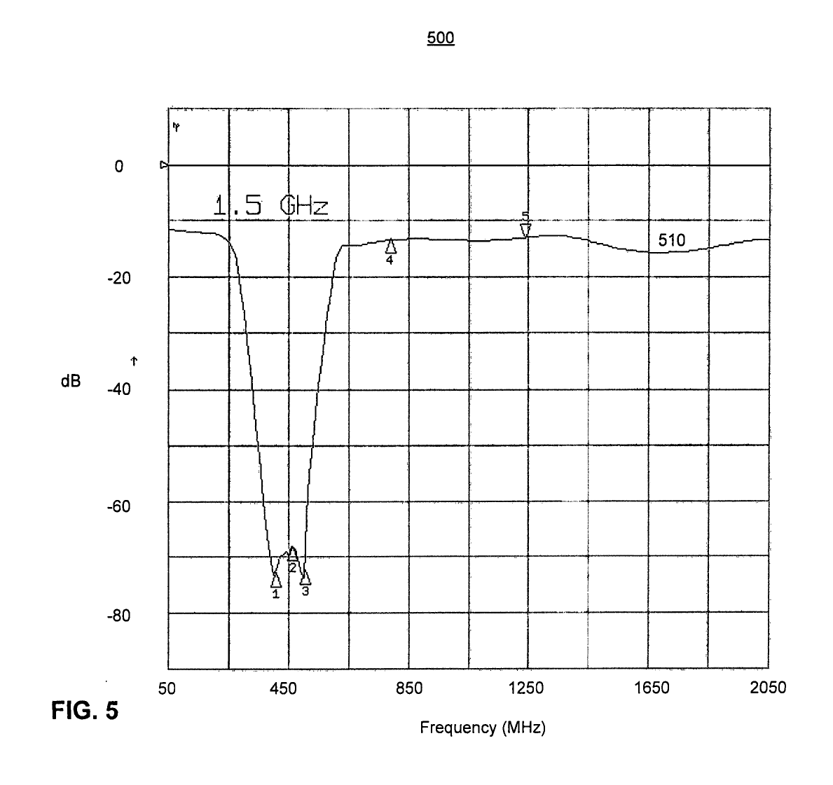

FIG. 5 shows the frequency response of the filter of FIG. 4. The x-axis shows signal frequency. The y-axis shows attenuation in dB. Allowing for 11.6 dB loss in the impedance matching pads, the passband loss is 1.5 to 2 dB. The average stopband attenuation across the MoCA band is 60 dB, which should be adequate.

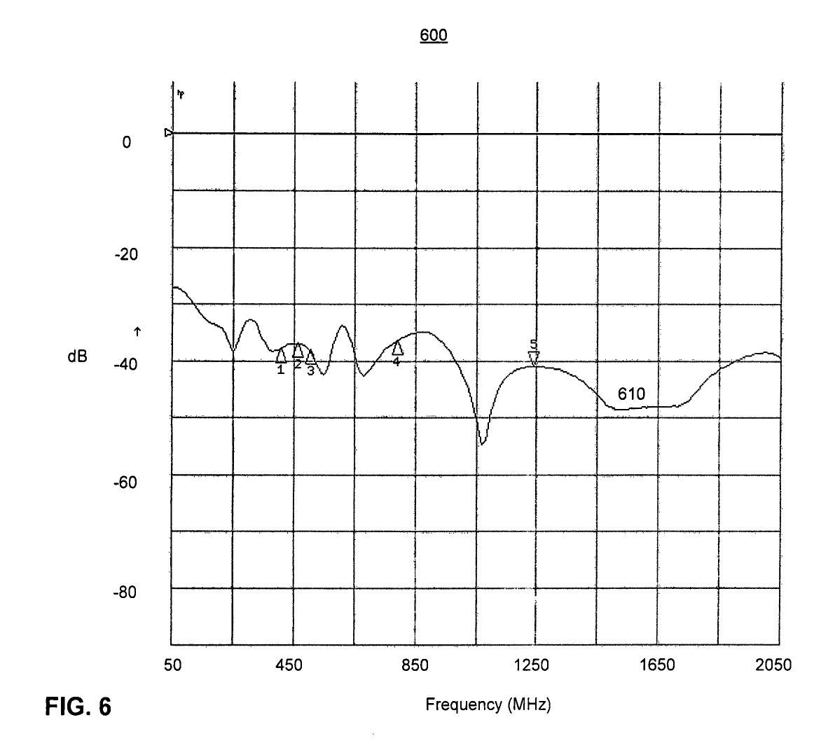

FIG. 6 shows a simulation of the attenuation of signals at various frequencies transmitted from output 5 to output 7 of an 8-way splitter with the output 470 of the filter of FIG. 4 connected to the splitter input and the input 460 terminated with a 75 Ohm terminator. As with FIG. 3, there is 11.6 dB loss in the matching pads used in the test system. Compared to the result shown in FIG. 3 using the Microphase filter, the sharp notch at 473 MHz is eliminated, greatly reducing the impact on communications in the MoCA band.

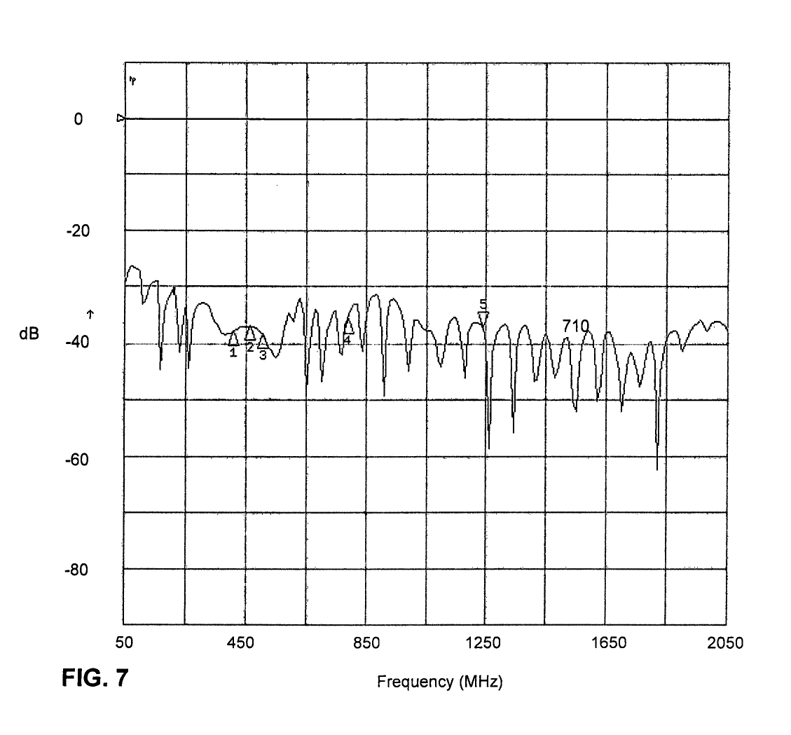

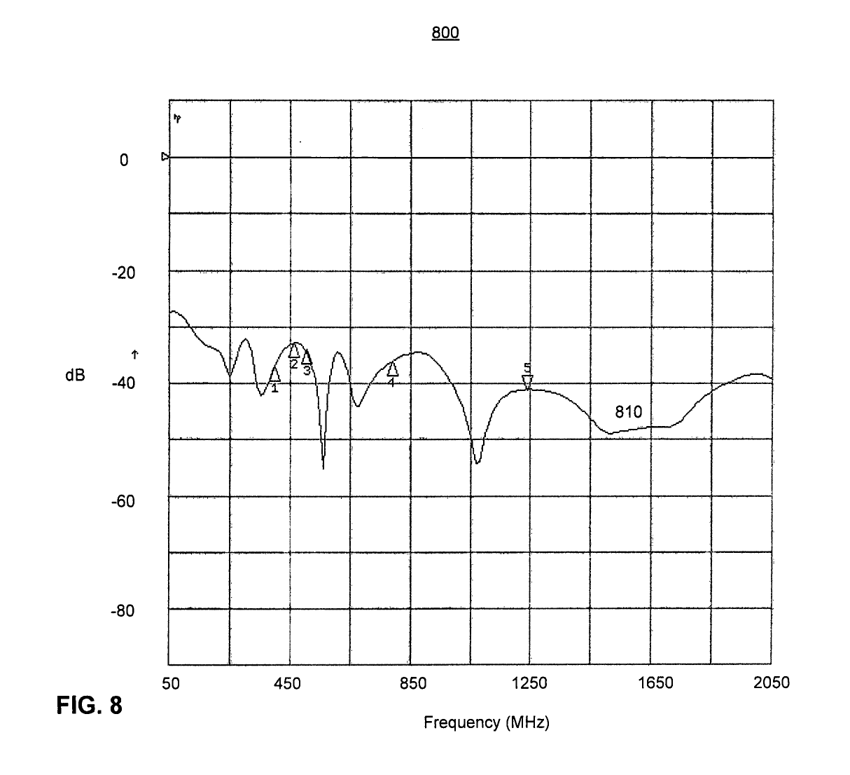

FIG. 7 shows the results for the configuration of FIG. 6 modified with the filter input 460 connected to a 3′ RG-59 coax cable instead of a termination. Note that the performance in the MoCA band is essentially unaffected. FIG. 8 shows the results for the configuration of FIG. 6 modified such that the value of resistor 457 is 33 Ohms. This controlled mismatch provides less cancellation in the MOCA band and a greater signal throughput without adversely affecting the isolation in the satellite band.

In each case, the performance of the splitter in conveying MoCA communications attached to the filter of the present invention is greatly improved over the performance achieved with the conventional bandstop filter. Furthermore, the required isolation of the filter input from the MoCA communications is maintained.

While the present invention has been described in terms of a specific embodiment, it will be appreciated that modifications may be made which will fall within the scope of the invention.

1. A filter apparatus comprising:
a bandstop filter (L1, L2,L3,C1,C2,C3) coupled to a first port (1) for filtering signals in a first signal band;
a parallel resonant circuit (C4, L4) coupled between said bandstop filter (L1, L2,L3,C1,C2,C3) and a second port (2) for filtering signals within said first signal band; and
a series resonant circuit (L5, C5) and a resistor (R1) coupled in series between said second port (2) and a source of reference potential wherein an impedance of said second port is adjusted in said first signal band in response to adjusting the value of said resistor (R1).

2. The filter apparatus of claim 1 wherein said bandstop filter (L1, L2,L3,C1,C2,C3) comprises:
a first circuit (C2, L2), comprising a first inductor (L2) and first capacitor (C2);
a second inductor (L3) and second capacitor (C3) in series coupling the input of said first circuit to said source of reference potential; and
a third inductor (L1) and third capacitor (C1) in series coupling the output of said first circuit to said source of reference potential.

3. The filter apparatus of claim 1 wherein said first port is coupled to a satellite signal source.

4. The filter apparatus of claim 1 wherein said second port is coupled to a signal splitter.

5. The filter apparatus of claim 1 wherein impedance at the output of said resonant circuit (C4, L4) for a first frequency band is higher than the impedance for the filter with said inductor, capacitor, and resistor in series coupling said second port to ground removed.

6. The filter apparatus of claim 1 wherein said first port is coupled to a signal source and the second port is coupled to a signal splitter for distributing signals within a video network.

7. The filter apparatus of claim 1 wherein said filter apparatus facilitates bidirectional communication in at least one frequency band.

8. An signal processing apparatus comprising:
a signal splitter having a first node for receiving a video signal, a second node coupled to a first processor and a third node coupled to a second processor;
a signal path for coupling a communications signal between said second node and said third node, said signal path further operative to impede the coupling of said video signal between said second node and said third node; and
a filter coupled between said first node and said source of said video signal for impeding the coupling of said communications signal from at least one of said second node and said third node to said source of said video signal, said filter comprising a bandstop filter coupled to a first port for filtering signals in a first signal band, a parallel resonant circuit coupled between said bandstop filter and a second port for filtering signals within said first signal band, and a series resonant circuit and a resistor coupled in series between said second port and a source of reference potential wherein an impedance of said second port is adjusted in said first signal band in response to adjusting the value of said resistor.

9. The signal processing apparatus of claim 8 wherein the frequency range attenuated by said bandstop filter is centered around approximately 550 MHz.

10. The signal processing apparatus of claim 8 wherein said bandstop filter provides substantial attenuation in a frequency range comprising 475 MHz to 650 MHz.

11. The filter apparatus of claim 8 wherein said source of said video signal is coupled to a satellite signal source.

12. A method of signal processing comprising the steps of:
receiving a signal at a first node;
providing a narrowband high impedance path to said signal between said first node and a second node;
providing a wideband high impedance path to said signal between said second node and a third node wherein said narrowband high impedance path has a frequency response within the frequency response of said wideband high impedance path; and
providing a narrowband low impedance path to said signal said first node and a source of an impedance, wherein said narrowband low impedance path and said narrowband high impedance path have approximately the same bandwidth and center frequency, and wherein adjusting said impedance alters an input impedance at said first node.

13. The method of signal processing of claim 12 wherein said center frequency is approximately 550 MHz.

14. The method of signal processing of claim 12 wherein said wideband high impedance path provides substantial attenuation in a frequency range comprising 475 MHz to 650 MHz.

15. The method of signal processing of claim 12 wherein said third node is coupled to a satellite signal source.

16. The method of signal processing of claim 12 wherein said first node is coupled to a signal splitter for distributing satellite signals to a plurality of satellite signal processors.

17. The method of signal processing of claim 12 wherein said wideband high impedance path provides a high impedance over a bandwidth covering a multimedia over coax alliance (MoCA) frequency range.

18. The method of signal processing of claim 12 wherein said said center frequency is approximately the center frequency of a multimedia over coax alliance (MoCA) frequency range.
